(19) United States
(12) Patent Application Publication
(10) Pub. No.: US 2009/0039512 A1
(43) Pub. Date: Feb. 12, 2009

(54) ELECTROMIGRATION RESISTANT INTERCONNECT STRUCTURE

(75) Inventors: Haining S. Yang, Wappingers Falls, NY (US); Chih-Chao Yang, Glenmont, NY (US); Keith Kwong Hon Wong, Wappingers Falls, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/835,678

(22) Filed: Aug. 8, 2007

(51) Int. Cl. H01L 23/52; H01L 21/4763

(52) U.S. Cl. 257/751; 438/653; 257/E23.141; 257/E21.495

(57) ABSTRACT

A line trench is formed in a dielectric layer that may contain an interlayer dielectric material. A metal liner is formed on the sidewalls and the bottom surface of the line trench. A conductive metal is deposited within a remaining portion of the line trench at least up to a top surface of the dielectric layer and planarized to form a metal line in the line trench. The metal line is recessed by a recess etch below the top surface of the dielectric layer. A dielectric line cap or a metallic line cap is formed by deposition of a dielectric cap layer or a metallic cap layer, followed by planarization of the dielectric or metallic cap layer. The dielectric line cap or the metallic line cap applies a highly compressive stress on the underlying metal line, which increases electromigration resistance of the metal line.

### FIELD OF THE INVENTION

The present invention relates to semiconductor structures, and particularly to electromigration resistant metal interconnect structures and methods of manufacturing thereof.

### BACKGROUND OF THE INVENTION

A metal line comprises a lattice of metal ions and non-localized free electrons. The metal ions are formed from metal atoms that donate some of their electrons to a common conduction band of the lattice, and the non-localized free electrons move with relatively small resistance within the lattice under an electric field. Normal metal lines, excluding superconducting materials at or below a superconducting temperature, have finite conductivity, which is caused by interaction of electrons with crystalline imperfections and phonons which are thermally induced lattice vibrations.

When electrical current flows in the metal line, the metal ions are subjected to an electrostatic force due to the charge of the metal ion and the electric field to which the metal ion is exposed to. Further, as electrons scatter off the lattice during conduction of electrical current, the electrons transfer momentum to the metal ions in the lattice of the conductor material. The direction of the electrostatic force is in the direction of the electric field, i.e., in the direction of the current, and the direction of the force due to the momentum transfer of the electrons is in the direction of the flow of the electrons, i.e., in the opposite direction of the current. However, the force due to the momentum transfer of the electrons is in general greater than the electrostatic force. Thus, metal ions are subjected to a net force in the opposite direction of the current, or in the direction of the flow of the electrons.

High defect density, i.e., smaller grain size of the metal, or high temperature typically increases electron scattering, and consequently, the amount of momentum transfer from the electrons to the conductor material. Such momentum transfer, if performed sufficiently cumulatively, may cause the metal ions to dislodge from the lattice and move physically. The mass transport caused by the electrical current, or the movement of the conductive material due to electrical current, is termed electromigration in the art.

In applications where high direct current densities are used, such as in metal interconnects of semiconductor devices, electromigration causes a void in a metal line or in a metal via. Such a void results in a locally increased resistance in the metal interconnect, or even an outright circuit “open.” In this case, the metal line or the metal via no longer provides a conductive path in the metal interconnect. Formation of voids in the metal line or the metal via can thus result in a product failure in semiconductor devices.

FIG. 1 shows a prior art metal interconnect structure comprising a dielectric layer 10, a metal liner 19, a metal line 29, and a dielectric cap layer 39. A top surface of the metal line 29 is substantially coplanar with a top surface of the dielectric layer 10. The dielectric cap layer 39 is located above the coplanar top surfaces of the dielectric layer 10, the metal liner 19, and the metal line 29. Irrespective of the properties of the dielectric cap layer 39, the dielectric cap layer 39 does not apply any appreciable level of stress to any underlying structure since a planar interface between the dielectric cap layer 39 and the underlying structures precludes any substantial transfer of stress from the dielectric cap layer 39 onto the underlying structures. The function of the dielectric cap layer 19 is primarily to provide mechanical support and protection from mobile ions and contaminants to the underlying metal line 29 in the prior art. The prior art metal interconnect structure displays a level of electromigration resistance known in the art.

In addition, the prior art metal interconnect structure comprise the dielectric cap layer 39 that extends laterally outside the region directly above the metal line 29. Since the dielectric cap layer 39 typically comprises silicon nitride or silicon carbide, which typically has a higher dielectric constant than the dielectric layer 10, the laterally extending portion of the dielectric cap layer 39 contributes to an increase of parasitic capacitance of the prior art metal interconnect structure.

FIG. 2 shows a vertical cross-sectional scanning electron micrograph (SEM) of an exemplary prior art metal interconnect structure comprising a first level metal line (M1 line), a first level via (V1), and a second level metal line (M2 line). The exemplary prior art metal interconnect structure contains a void in the second level metal line above the first level via. This void is caused by electromigration once the interconnect structure is subjected to a stress condition that mimics prolonged usage of the interconnect structure above a sustainable level of current density. Due to the formation of the void, the first metal line and the second metal line are electrically disconnected. Such void, if formed in a semiconductor device, may cause a circuit failure, and possibly, a device failure.

As feature sizes of semiconductor devices continue to shrink, current density through metal interconnect structures increase, causing the metal interconnect structures to be more prone to electromigration failure. Such electromigration failure increases the frequency of product failure over a lifetime of semiconductor devices, and consequently, degrades reliability of the semiconductor devices. Thus, prevention of electromigration failure becomes more important in each new generation of semiconductor technology to provide reliable semiconductor devices.

In research leading to the present invention, it has been observed that metal ions may be transported along the interface between the metal line and a dielectric line cap, and that such metal ion transport plays an important role on electromigration failure.

In view of the above, there exists a need to provide an electromigration resistant metal interconnect structure for semiconductor applications, and methods of providing the same.

Further, lateral extension of a dielectric cap layer outside the region immediately above a metal line contributes to an increased parasitic capacitance of the prior art metal interconnect structure.

Therefore, there exists a need to provide an electromigration resistant metal interconnect structure having a reduced parasitic resistance, and methods of manufacturing the same.

### SUMMARY OF THE INVENTION

The present invention addresses the needs described above by providing a metal interconnect structure having a higher resistance to electromigration compared to prior art structures, and methods of manufacturing the electromigration resistant metal interconnect structure.

A line trench is formed in a dielectric layer that may contain an interlayer dielectric material. A metal liner is formed on the sidewalls and the bottom surface of the line trench. A conductive metal is deposited within a remaining portion of the line trench at least up to a top surface of the dielectric layer and planarized to form a metal line in the line trench. The metal line is recessed by a recess etch below the top surface of the dielectric layer. A dielectric line cap or a metallic line cap is formed by deposition of a dielectric cap layer or a metallic cap layer, followed by planarization of the dielectric or metallic cap layer. The dielectric line cap or the metallic line cap applies a highly compressive stress on the underlying metal line, which increases electromigration resistance of the metal line. The dielectric line cap or the metal line cap does not extend laterally outside the region immediately above the metal line, resulting in a reduced parasitic resistance compared with prior art metal interconnect structures.

According to an aspect of the present invention, a metal interconnect structure is provided, which comprises:

a dielectric layer containing a line trench;

a metal liner abutting sidewalls and a bottom surface of the line trench;

a metal line located in the line trench, wherein sidewalls and a bottom surface of the metal line abut the metal liner; and

a dielectric line cap abutting a top surface of the metal line and an upper portion of inner sidewalls of the metal liner.

In one embodiment, the dielectric line cap has a top surface that is substantially coplanar with a top surface of the dielectric layer, and laterally confined by the inner sidewalls of the metal liner.

In another embodiment, the dielectric line cap applies a compressive stress to a top portion of the metal line.

In even another embodiment, the laterally compressive stress is a laterally compressive stress having a magnitude from about 0.5 GPa to about 4 GPa.

In yet another embodiment, the dielectric line cap comprises an ultraviolet radiation cured silicon nitride, which has altered chemical bondings due to an ultraviolet radiation treatment.

In still another embodiment, the metal line has a current density under use condition (Jᵤₛₑ) greater than about 60 mA/μm².

In a still yet another embodiment, the dielectric line cap applies a laterally tensile stress to a top portion of the dielectric layer.

In a further embodiment, the dielectric layer comprises at least one of an oxide based dielectric material, a spin-on low-k dielectric material, a chemical vapor deposition (CVD) low-k dielectric material, and a stack thereof, and the metal liner comprises one of Ti, TiN, Ta, TaN, WN, and CoWP, and the metal line comprises one of Cu and Al, and the metal line is encapsulated by the metal liner and the dielectric line cap.

According to another aspect of the present invention, another metal interconnect structure is provided, which comprises:

a dielectric layer containing a line trench;

a metal liner abutting sidewalls and a bottom surface of the line trench;

a metal line located in the line trench, wherein sidewalls and a bottom surface of the metal line abut the metal liner; and

a metallic line cap abutting a top surface of the metal line and an upper portion of inner sidewalls of the metal liner.

In one embodiment, the metallic line cap has a top surface that is substantially coplanar with a top surface of the dielectric layer, and laterally confined by the inner sidewalls of the metal liner.

In another embodiment, the metallic line cap applies a compressive stress to a top portion of the metal line.

In even another embodiment, the laterally compressive stress is a laterally compressive stress having a magnitude from about 1 GPa to about 5 GPa.

In yet another embodiment, the metallic line cap comprises one of Ti, TiN, Ta, TaN, WN, and CoWP.

In still another embodiment, the metal line has a current density under use condition (Jᵤₛₑ) greater than about 60 mA/μm².

In a further embodiment, the dielectric layer comprises at least one of a conventional oxide based dielectric material, a spin-on low-k dielectric material, a chemical vapor deposition (CVD) low-k dielectric material, and a stack thereof, and the metal liner comprises one of Ti, TiN, Ta, TaN, WN, and CoWP, and the metal line comprises one of Cu and Al, and the metal line is encapsulated by the metal liner and the metallic line cap.

According to yet another aspect of the present invention, a method of manufacturing a metal interconnect structure is provided, which comprises:

forming a line trench in a dielectric layer;

forming a metal liner and a metal line in the trench, wherein top surfaces of the dielectric layer, the metal liner, and the metal line are substantially coplanar;

recessing the metal line selective to the metal liner and the dielectric layer to a depth; and

forming a line cap having a top surface that is coplanar with the top surfaces of the dielectric layer and the metal liner and vertically abutting the recessed metal line.

In one embodiment, the line cap is laterally confined by inner sidewalls of the metal liner and vertically confined between the top surfaces of the dielectric layer and the metal liner and a top surface of the recessed metal line.

In another embodiment, the line cap comprises a stress generating material that applies a compressive stress to a top portion of the metal line.

In even another embodiment, the compressive stress is a laterally compressive stress having a magnitude from about 0.5 GPa to about 5 GPa.

In yet another embodiment, the line cap is one of a dielectric line cap and a metallic line cap.

In still another embodiment, the line cap comprises one of ultraviolet radiation cured silicon nitride, Ti, TiN, Ta, TaN, WN, and CoWP.

In still yet another embodiment, the metal line has a current density under use condition (Jᵤₛₑ) greater than about 60 mA/μm².

In a further embodiment, the dielectric layer comprises at least one of a conventional oxide based dielectric material, a spin-on low-k dielectric material, a chemical vapor deposition (CVD) low-k dielectric material, and a stack thereof, and the metal liner comprises one of Ti, TiN, Ta, TaN, WN, and CoWP, and the metal line comprises one of Cu and Al, and the metal line is encapsulated by the metal liner and the line cap.

### BRIEF DESCRIPTION OF THE DRAWINGS

FIG. 1 is a prior art metal interconnect structure.

FIG. 2 is a vertical cross-sectional scanning electron micrograph (SEM) of an exemplary prior art metal interconnect structure containing an electromigration induced void in a metal line.

FIGS. 3-7, 9 and 10 are sequential vertical cross-sectional views of a first exemplary metal interconnect structure according to a first embodiment of the present invention.

FIG. 8 is a scanning electron micrograph (SEM) of a vertical cross-section of a physical implementation of the first exemplary metal interconnect structure at a manufacturing stage corresponding to FIG. 7.

FIG. 11 is a simulated two-dimensional contour plot of lateral stress of the first exemplary metal interconnect structure, in which a lateral stress to the left is considered compressive and a lateral stress to the right is considered tensile.

FIGS. 12 and 13 are sequential vertical cross-sectional views of a second exemplary metal interconnect structure according to a second embodiment of the present invention.

FIG. 14 is a Weibull plot of cumulative failure rate as a function of a logarithm of stress time, which shows performance of the exemplary metal interconnect structures according to the present invention.

### DETAILED DESCRIPTION OF THE INVENTION

As stated above, the present invention relates to electromigration resistant metal interconnect structures and methods of manufacturing thereof, which is now described in detail with accompanying figures. It is noted that like and corresponding elements are referred to by like reference numerals.

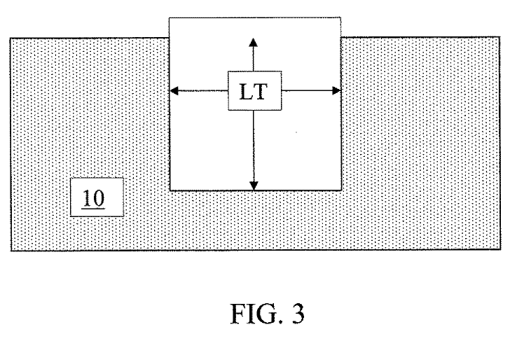

Referring to FIG. 3, a first exemplary metal interconnect structure according to a first embodiment of the present invention comprises a dielectric layer 10 containing a line trench LT, or a trench formed along a line. The sidewalls of the line trench LT may be substantially vertical, or may have an inward taper so that the bottom surface of the line trench LT is narrower than the opening at the top portion of the line trench LT. The taper angle may be from 0 degree to about 30 degrees, and typically from about 5 degrees to about 20 degrees, depending on the material of the dielectric layer 10, the width of the opening at the top portion of the line trench LT, the etch chemistry employed in etching the line trench LT, and the depth of the line trench LT.

The dielectric layer 10 may comprise an oxide based conventional dielectric material, which has a dielectric constant k from about 3.6 to about 3.9, or a low-k dielectric material, which has a dielectric constant k of about 3.0 or less, preferably less than about 2.8, and more preferably less than about 2.5. Non-limiting examples of the oxide based conventional dielectric material included undoped silicate glass (USG), fluorosilicate glass (FSG), borophosphosilicate glass (BPSG), and phosphosilicate glass (PSG). The low-k dielectric material may be a spin-on low-k dielectric material or a CVD low-k dielectric material, i.e., a low-k dielectric material deposited by chemical vapor deposition (CVD). An example of the spin-on low-k dielectric material is a thermosetting polyarylene ether, which is also commonly referred to as “Silicon Low-K”, or “SiLK™.” The term “polyarylene” is used herein to denote aryl moieties or inertly substituted aryl moieties which are linked together by bonds, fused rings, or inert linking groups such as oxygen, sulfur, sulfone, sulfoxide, carbonyl, etc. Composition and deposition methods of the CVD low-k dielectric material are well known in the art. For example, the CVD low-k dielectric material may be a SiCOH dielectric containing a matrix of a hydrogenated oxidized silicon carbon material (SiCOH) comprising atoms of Si, C, O and H in a covalently bonded tri-dimensional network. Both the spin-on low-k dielectric material and the CVD low-k dielectric material may be porous, which decreases the dielectric constant of the dielectric layer 10. The dielectric layer 10 may comprise a stack of at least two of the oxide based conventional dielectric material, the spin-on low-k dielectric material, and the CVD low-k dielectric material.

The thickness of the dielectric layer 10 may be 50 nm to about 1 μm, with a thickness from 100 to about 500 nm being more typical, although lesser and greater thicknesses are explicitly contemplated herein. The depth of the line trench LT may be from about 20% to 80%, and typically from about 35% to about 65%, of the thickness of the dielectric layer 10, although lesser and greater percentages are explicitly contemplated herein.

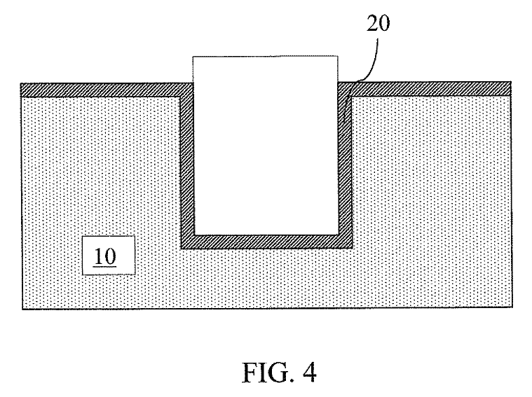

Referring to FIG. 4, a metal liner 20 is deposited on the sidewalls and the bottom surface of the line trench LT by physical vapor deposition (PVD), i.e., sputtering, chemical vapor deposition (CVD), electroplating, electroless plating, or a combination thereof. Thus, the metal liner 20 abuts the sidewalls and the bottom surface of the line trench LT. The metal liner 20 comprises an elemental metal or a metallic compound that provides good adhesion to the dielectric layer 10 and serves as a barrier for mobile ions and contaminants to protect the metal line 30, and prevents diffusion of the material of the metal line 30 into the dielectric layer 10. For example, the metal liner 20 may comprise one of Ti, TiN, Ta, TaN, WN, and CoWP.

The metal liner 20 may have the same, or different, thickness between a bottom portion that vertically abut the dielectric layer 10, and sidewall portions that substantially laterally abut the dielectric layer 10. The thickness of the bottom portion of the metal liner 20 is herein referred to as the thickness of the metal liner 20. The thickness of the metal liner 20 may be from about 3 nm to about 60 nm, and typically from about 10 nm to about 30 nm, although lesser and greater thicknesses are explicitly contemplated herein. The ratio between the thickness of the sidewall portions of the metal liner 20 to the thickness of the bottom portion of the metal liner 20, i.e., the “thickness of the metal liner” 20, is referred to as step coverage. The step coverage is dependent on the method of deposition of the metal liner 20, the taper angle of the sidewalls of the line trench, and the aspect ratio of the line trench LT, i.e., the ratio of the height to the width of the line trench LT. Typical values of the step coverage range from about 0.5 to 1, although lesser step coverage is also known. In general, chemical vapor deposition processes tend to provide higher step coverage than physical vapor deposition.

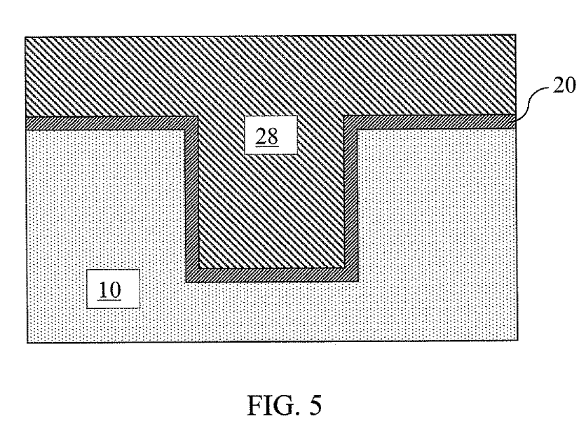

Referring to FIG. 5, a metal layer 28 is electroplated on the metal liner 20. The process of electroplating may include initial seeding of a thin layer of metal (not shown) by physical vapor deposition or by other means. The thickness of the metal layer 28 is at least equal to half of the width of the opening at the top of the metal liner to insure filling of the line trench LT. The metal layer 28 may be annealed at a relatively low temperature from about 100° C. to about 200° C. for a duration from about 30 minutes to about 2 hours. The process condition of the anneal may be optimized to promote growth of the grains in the metal layer. Typically, grain sizes having a characteristic dimension of about the width of the line trench LT is desired to lower resistivity of the metal layer 28.

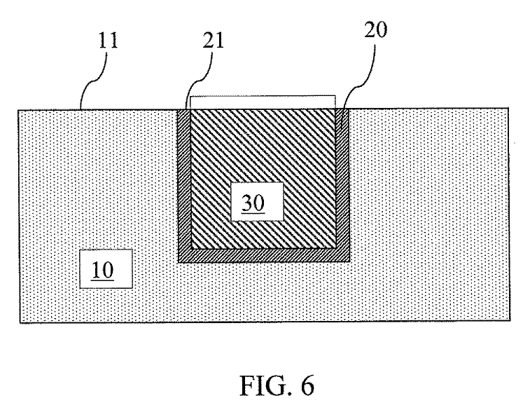

Referring to FIG. 6, the metal layer 28 is planarized to a dielectric layer top surface 11, i.e., a top surface of the dielectric layer 10, for example, by chemical mechanical polishing (CMP). A metal liner top surface 21, i.e., a top surface of the metal liner 20, is substantially coplanar with the dielectric layer top surface 11. The process of the chemical mechanical polishing (CMP) may employ a portion (See FIG. 5) of the metal liner 20 above the dielectric layer top surface 11 as a stopping layer. In this case, the CMP process may be a two step process in which a first step is a self-stopping process that removes the portion of the metal layer 28 above the metal liner 20, and a second step polishes the portion of the metal layer 21 above the dielectric layer top surface 11. After the CMP process, the remaining portion of the metal layer 28, which is laterally confined within inner sidewalls of the metal liner 20 and vertically confined within the dielectric layer top surface 11 and the bottom portion of the metal liner 20, constitutes a metal line 30. The metal line 30 comprises the same material as the metal layer 28.

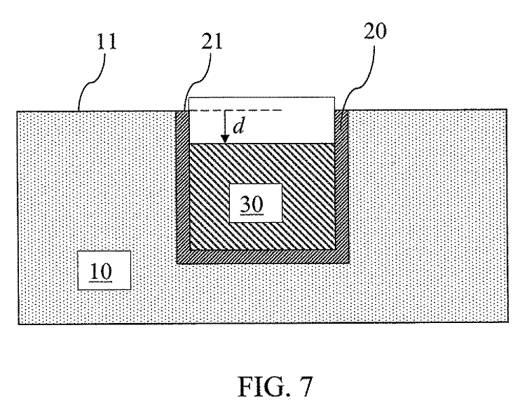

Referring to FIG. 7, the metal line 30 is recessed below the level of the dielectric layer top surface 11 by an etch selective to the metal liner 20 and the dielectric layer 10. In other words, the amount of removal of the metal liner 20 and the dielectric layer 10 is insignificant during the etch. The etch may be a wet etch or a reactive ion etch. The recess depth d may be from about 5 nm to about 60 nm, and preferably from about 10 nm to about 30 nm, although lesser and greater recess depths d are herein contemplated also. Preferably, the recess depth d is from about 1% to about 30%, and more preferably from about 5% to about 20%, of the height of the line trench LT (See FIG. 3), although the ratio of the recess depth d to the height of the line trench LT tends to decrease as the height of the line trench LT increases. The recessed surface of the metal line 30 may be level, convex, or concave. In other words, the recessed surface of the metal line 30 may be flat, bending downward toward the edge near the metal liner 20, or bending upward toward the edge near the metal liner 20. Preferably, the recessed surface of the metal line 30 is substantially flat.

The metal line 30 is an elongated line having a substantially rectangular or a trapezoidal cross-section having a greater width at a top than at a bottom. The elongated line runs perpendicular to the place of the vertical cross-sectional view of FIG. 3. The metal line 30 may comprise Cu, Al, or other conductive metal that may sputter deposited and/or electroplated on the metal liner 20. Preferably, the metal line 30 has a high electrical conductivity.

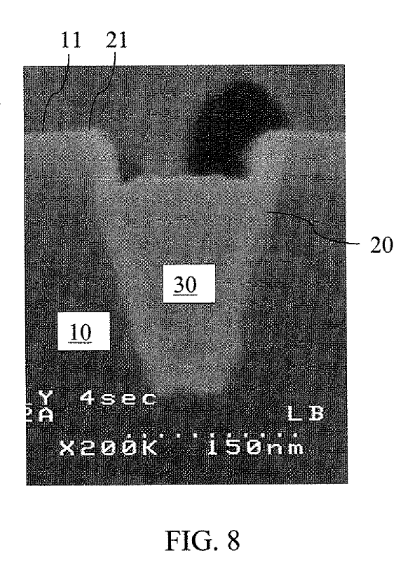

Referring to FIG. 8, a scanning electron micrograph (SEM) of a vertical cross-section of a physical implementation of the first exemplary metal interconnect structure at a manufacturing stage corresponding to FIG. 7. The physical implementation has a line trench sidewall taper angle of approximately 15 degrees and a substantially conformal metal liner 20 having a thickness of about 12 nm. The height of the line trench is about 220 nm and the recess depth d is about 45 nm. The metal liner top surface 21 is substantially level with the dielectric layer top surface 11.

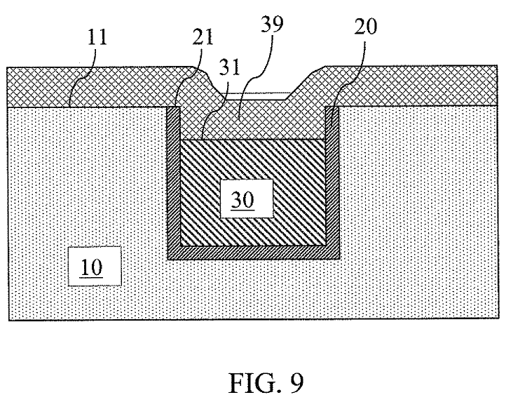

Referring to FIG. 9, a dielectric line cap layer 39 is deposited on the recessed surface of the metal line 30, a top portion of inner sidewalls of the metal liner 20, and the dielectric layer top surface 11. The recessed surface of the metal line 30 is herein referred to a metal line top surface 31. Preferably, the thickness of the dielectric line cap layer 39 is at least equal to the recess depth d, and may be from about 5 nm to about 100 nm, and preferably from about 12 nm to about 50 nm, although lesser and greater thicknesses are herein contemplated also.

The dielectric line cap layer 39 comprises a stress-generating material that may apply a compressive stress on a structure directly underneath. For example, the dielectric line cap liner 39 may comprise an ultraviolet radiation cured silicon nitride. An ultraviolet radiation cured silicon nitride may be formed by depositing a silicon nitride film by a chemical vapor deposition, e.g., plasma enhanced chemical vapor deposition (PECVD) or high density plasma chemical vapor deposition (HDPCVD), followed by irradiation of the deposited silicon nitride film with a mercury broad band spectrum light source for a duration from about 10 to about 20 minutes at a temperature from about 350° C. to about 480° C. at a pressure from about 100 mTorr to about 600 mTorr in a He or Ar ambient. The ultraviolet radiation causes re-arrangement of the chemical bonding of the silicon nitride material, resulting in a significant increase in the stress. Alternate methods of irradiating the silicon nitride by alternate light sources, and modifications in the processing conditions in terms of the duration of the treatment, temperature, pressure, and ambient gases are explicitly contemplated herein. Such ultraviolet radiation cured silicon nitride may have a stress level from about 0.5 GPa to about 4 GPa, and typically from about 2 GPa to about 3 GPa.

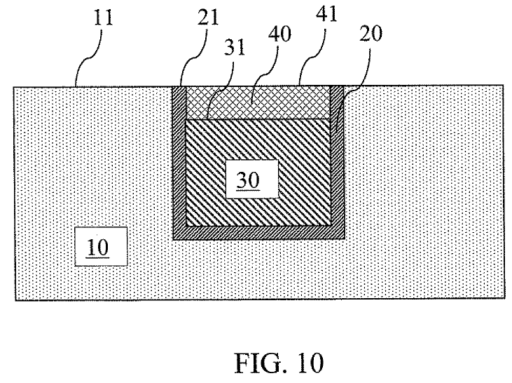

Referring to FIG. 10, the dielectric line cap layer 39 is planarized, for example, by chemical mechanical polishing (CMP) to form a dielectric line cap 40. A dielectric line cap top surface 41, i.e., a top surface of the dielectric line cap 40, is substantially flush with the dielectric layer top surface 11 and the metal liner top surface 21. Thus, the dielectric line cap 40 is laterally bounded by the upper portions of the inner sidewalls of the metal liner 20, and vertically bounded by the dielectric layer top surface 11 and the metal line top surface 31. The thickness of the dielectric line cap 40 is substantially the same as the recess depth d, and may be from about 5 nm to about 60 nm, and preferably from about 10 nm to about 30 nm, although lesser and greater recess depths d are herein contemplated also.

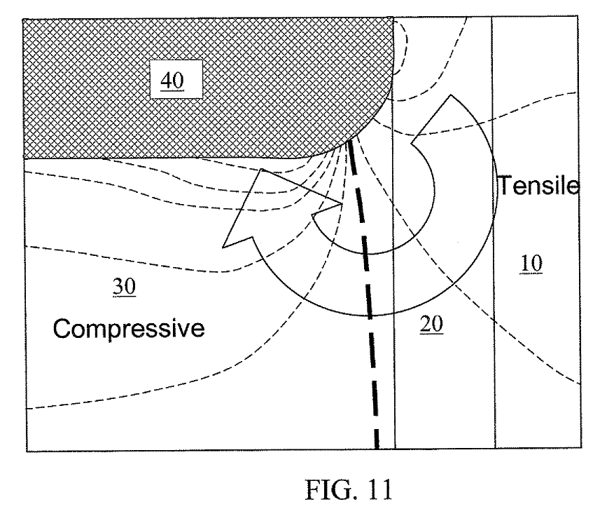

Referring to FIG. 11, result of a two-dimensional simulation is shown, in which the geometry of the first exemplary metal interconnect structure is approximated by a two dimensional model of a stress-generating dielectric line cap 40 having an intrinsic stress level of an ultraviolet radiation cured silicon nitride material disposed on a metal line 30 and laterally abutting an upper portion of inner sidewalls of a metal liner 20 embedded in a dielectric layer 10. Variations in lateral stress are displayed by contours representing the same level of lateral stress. A lateral stress toward the left side of the plot, i.e., a lateral stress toward the center of the metal line 30, is considered compressive since such a lateral stress physically compresses, i.e., results in a strain reducing lateral physical dimensions, a physical structure. A lateral stress toward the right side of the plot, i.e., a lateral stress in the direction from the center of the metal line 30 to the dielectric layer 10, is considered tensile since such a lateral stress stretched a physical structure.

The line of zero lateral stress is represented by a thick dotted line. The various dotted lines represent contours of equal lateral stress, of which dotted lines to the left of the thick dotted line represents contours of equal lateral compressive stress and the dotted lines to the right of the thick dotted line represents contours of equal lateral tensile stress. The spacing of the successive dotted lines correspond to approximately equal increments or decrease in the lateral stress. The lateral stress becomes more compressive in the direction of the clockwise arrow. The degree of rounding of the edge of the dielectric line cap 40 adjoining the line of zero lateral stress determines the detailed features of the various dotted lines near the edge including the magnitude of the gradient of the lateral stress. In general, the dielectric line cap 40 applies a lateral compressive stress to a top portion of the metal line. While the magnitude of the lateral compressive may be dependent on the geometry and the material of the dielectric line cap, the magnitude of the lateral compressive stress may be from about 0.5 GPa to about 4 GPa, and typically from about 2 GPa to about 3 GPa for an ultraviolet radiation cured silicon nitride.

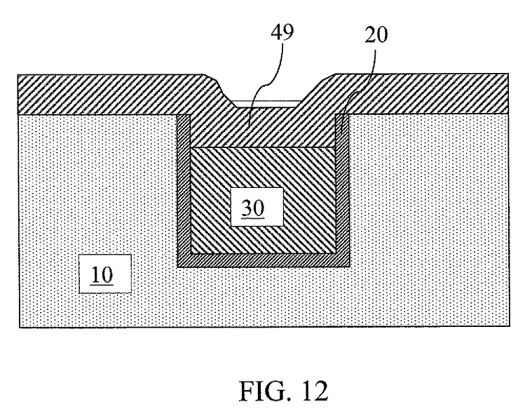

Referring to FIG. 12, a second exemplary metal interconnect structure according to a second embodiment of the present invention is derived from the first exemplary metal interconnect structure of FIG. 7 by depositing a metallic line cap layer 49 on the metal line top surface 31, a top portion of inner sidewalls of the metal liner 20, and the dielectric layer top surface 11. Preferably, the thickness of the metallic line cap layer 49 is at least equal to the recess depth d, and may be from about 5 nm to about 100 nm, and preferably from about 12 nm to about 50 nm, although lesser and greater thicknesses are herein contemplated also.

The metallic line cap layer 49 comprises a stress-generating material that may apply a compressive stress on a structure directly underneath. For example, the metallic line cap liner 39 may comprise one of Ti, TiN, Ta, TaN, WN, and CoWP. The metallic line cap liner 39 may, or may not, comprise the same material as the metal line 20. The metallic line cap liner 39 may be formed by chemical vapor deposition, physical vapor deposition, or a combination thereof. Electroplating or electroless plating followed by a seeding of seed layer may be employed as well. Other sputtered metal or reactively sputtered metal nitride that generates a compressive stress as deposited may be employed as well. Compressive stress on the order of 1 GPa to 5 GPa have been reported, depending strongly on deposition condition and tooling.

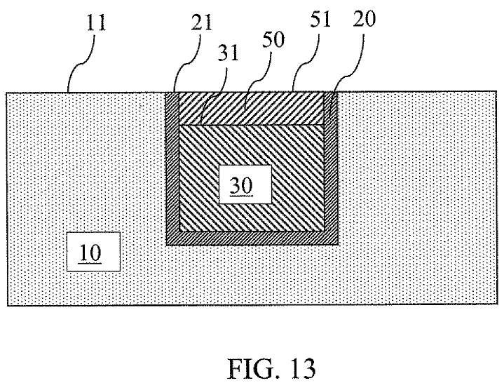

Referring to FIG. 13, the metallic line cap layer 49 is planarized, for example, by chemical mechanical polishing (CMP) to form a metallic line cap 50. A metallic line cap top surface 51, i.e., a top surface of the metallic line cap 50, is substantially flush with the dielectric layer top surface 11 and the metal liner top surface 21. Thus, the metallic line cap 50 is laterally bounded by the upper portions of the inner sidewalls of the metal liner 20, and vertically bounded by the dielectric layer top surface 11 and the metal line top surface 31. The thickness of the metallic line cap 50 is substantially the same as the recess depth d, and may be from about 5 nm to about 60 nm, and preferably from about 10 nm to about 30 nm, although lesser and greater recess depths d are herein contemplated also.

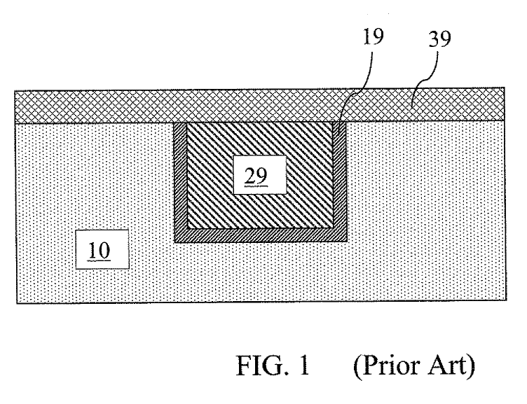

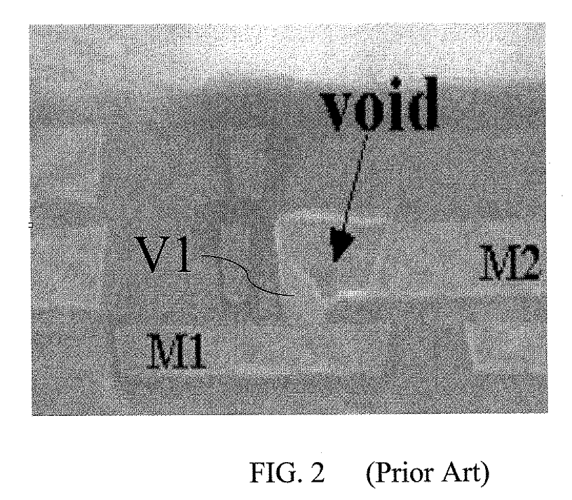

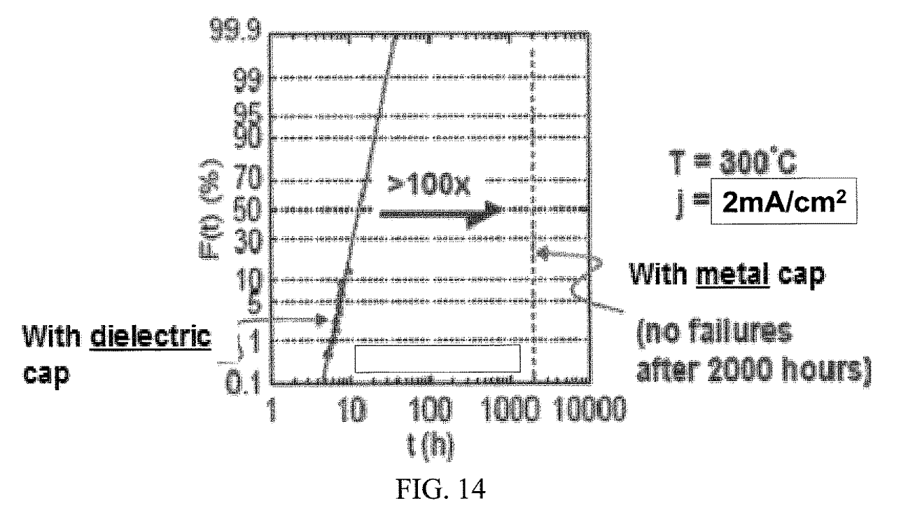

Beneficial effect of the laterally compressive stress on electromigration resistance has been empirically verified. Referring to FIG. 14, a Weibull plot of cumulative failure rate of a test structure containing multiple linked lines and vias as a function of a logarithm of stress time is shown. The Weibull plot shows a straight line that is fitted to a set of data points representing cumulative failure count of a test structure employing the inventive dielectric line cap 40 of the first embodiment of the present invention. From the position and slope of the fitted line, a current density under use condition (Jᵤₛₑ) is calculated for the test structure employing the inventive dielectric line cap 40. The current density under use condition (Jᵤₛₑ) is the maximum current density that would give a cumulative failure rate of 1.0×10⁻¹¹ per interconnect at 100 C. after 100,000 hours. The current density under use condition (Jᵤₛₑ) is calculated by measuring failure rate of test structures under a test condition that accelerates electromigration failure rates. Similar testing has been performed with other test structures in which the prior art structure of FIG. 1 is employed and the dielectric line cap layer 39 employed a low stress silicon nitride that is treated with ultraviolet light. The low stress silicon nitride applies a low tensile stress, i.e., a tensile stress of less than 0.3 GPa in magnitude, on an underlying structure. Test results are tabulated in Table 1 below.

TABLE 1
Comparison of current density under use condition (Jᵤₛₑ) between electromigration
test structures employing a ultraviolet radiation cured silicon nitride line cap
and an ultraviolet radiation treated silicon nitride line cap layer.

| Sample | | | | |
|---|---|---|---|---|
| Group | Structure of silicon | | Stress on an underlying | |
| Number | nitride | Thickness | metal line | Jᵤₛₑ |
| 1 | Cap layer over metal | 20 nm | Tensile, <0.3 GPa | 51 mA/μm² |
| | line and dielectric layer | | | |
| 2 | Cap layer over metal | 20 nm | Tensile, <0.3 GPa | 52 mA/μm² |
| | line and dielectric layer | | | |
| 3 | Cap over metal line | 20 nm | Compressive, >0.5 GPa | 106 mA/μm² |
| | only | | | |
| 4 | Cap over metal line | 25 nm | Compressive, >0.5 GPa | 91 mA/μm² |
| | only | | | |
| 5 | Cap over metal line | 25 nm | Compressive, >0.5 GPa | 99 mA/μm² |
| | only | | | |

Comparison of the data from the test groups 3-5 with the data from the test groups 1 and 2 show that current density under use condition (Jᵤₛₑ) is greater than 60 mA/μm². The inventive metal interconnect structure according to the first embodiment of the present invention provides a superior electromigration resistance to the prior art structure.

Further examination of FIG. 14 shows that no fail was observed for test structures employing a metallic line cap according to the second embodiment of the present invention. The non-detectable electromigration failure rate of the test structure with the metallic line cap results in an expected product lifetime about 100 times longer than the expected product lifetime at the same operating current level. While calculation of the value of current density under use condition (Jᵤₛₑ) is difficult due to lack of any fail, the current density under use condition (Jᵤₛₑ) for the test structures employing the metallic line cap is greater than the current density under use condition (Jᵤₛₑ) of the test structures with the dielectric line cap. In practice, the current density under use condition (Jᵤₛₑ) for the test structures employing the metallic line cap is far above 100 mA/μm².

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A metal interconnect structure comprising:
a dielectric layer containing a line trench;
a metal liner abutting sidewalls and a bottom surface of said line trench;
a metal line located in said line trench, wherein sidewalls and a bottom surface of said metal line abut said metal liner; and
a dielectric line cap abutting a top surface of said metal line and an upper portion of inner sidewalls of said metal liner.

2. The metal interconnect structure of claim 1, wherein said dielectric line cap has a top surface that is substantially coplanar with a top surface of said dielectric layer, and laterally confined by said inner sidewalls of said metal liner.

3. The metal interconnect structure of claim 1, wherein said dielectric line cap applies a compressive stress to said metal line.

4. The metal interconnect structure of claim 3, wherein said compressive stress is a laterally compressive stress having a magnitude from about 0.5 GPa to about 4 GPa.

5. The metal interconnect structure of claim 4, wherein said dielectric line cap comprises an ultraviolet radiation cured silicon nitride.

6. The metal interconnect structure of claim 1, wherein said metal line has a current density under use condition (Jᵤₛₑ) greater than about 60 mA/μm².

7. The metal interconnect structure of claim 1, wherein said dielectric layer comprises at least one of an oxide based dielectric material, a spin-on low-k dielectric material, a chemical vapor deposition (CVD) low-k dielectric material, and a stack thereof, and said metal liner comprises one of Ti, TiN, Ta, TaN, WN, and CoWP, and said metal line comprises one of Cu and Al, and said metal line is encapsulated by said metal liner and said dielectric line cap.

8. A metal interconnect structure comprising:
a dielectric layer containing a line trench;
a metal liner abutting sidewalls and a bottom surface of said line trench;
a metal line located in said line trench, wherein sidewalls and a bottom surface of said metal line abut said metal liner; and
a metallic line cap abutting a top surface of said metal line and an upper portion of inner sidewalls of said metal liner.

9. The metal interconnect structure of claim 8, wherein said metallic line cap has a top surface that is substantially coplanar with a top surface of said dielectric layer, and laterally confined by said inner sidewalls of said metal liner.

10. The metal interconnect structure of claim 8, wherein said metallic line cap applies a compressive stress to said metal line.

11. The metal interconnect structure of claim 10, wherein said compressive stress is a laterally compressive stress having a magnitude from about 1 GPa to about 5 GPa.

12. The metal interconnect structure of claim 10, wherein said metallic line cap comprises one of Ti, TiN, Ta, TaN, WN, and CoWP.

13. The metal interconnect structure of claim 8, wherein said metal line has a current density under use condition (Jᵤₛₑ) greater than about 60 mA/μm².

14. A method of manufacturing a metal interconnect structure comprising:
forming a line trench in a dielectric layer;
forming a metal liner and a metal line in said trench, wherein top surfaces of said dielectric layer, said metal liner, and said metal line are substantially coplanar;
recessing said metal line selective to said metal liner and said dielectric layer to a depth; and
forming a line cap having a top surface that is coplanar with said top surfaces of said dielectric layer and said metal liner and vertically abutting said recessed metal line.

15. The method of claim 14, wherein said line cap is laterally confined by inner sidewalls of said metal liner and vertically confined between said top surfaces of said dielectric layer and said metal liner and a top surface of said recessed metal line.

16. The method of claim 14, wherein said line cap comprises a stress generating material that applies a compressive stress to a top portion of said metal line.

17. The method of claim 16, wherein said compressive stress is a laterally compressive stress having a magnitude from about 0.5 GPa to about 5 GPa.

18. The method of claim 14, wherein said line cap is one of a dielectric line cap and a metallic line cap.

19. The method of claim 14, wherein said line cap comprises one of ultraviolet radiation cured silicon nitride, Ti, TiN, Ta, TaN, WN, and CoWP.

20. The method of claim 14, wherein said metal line has a current density under use condition (Jᵤₛₑ) greater than about 60 mA/μm².
